(19) United States
(12) Patent Application Publication
(10) Pub. No.: US 2012/0306101 A1
(43) Pub. Date: Dec. 6, 2012

(54) SEMICONDUCTOR DEVICE

(75) Inventor: Masaki TAMARU, Kyoto (JP)

(73) Assignee: Panasonic Corporation, Osaka (JP)

(21) Appl. No.: 13/586,403

(22) Filed: Aug. 15, 2012

Related U.S. Application Data
(63) Continuation of application No. PCT/JP2011/000926, filed on Feb. 18, 2011.

(30) Foreign Application Priority Data
Mar. 29, 2010 (JP) 2010-075972

(51) Int. Cl. H01L 23/48

(52) U.S. Cl. 257/774; 257/E23.011

(57) ABSTRACT

A power line structure is implemented which is capable of securing large interconnection resources for signal lines while suppressing a power supply voltage drop. Power supply potential lines and substrate potential lines are formed in a first wiring layer, and power supply strap lines are formed in a wiring layer that is located below the center of the overall height of the wiring layers. Upper via portions are arranged at a lower density in the direction in which the power supply strap lines extend than lower via portions.

### CROSS-REFERENCE TO RELATED APPLICATION

This is a continuation of PCT International Application PCT/JP2011/000926 filed on Feb. 18, 2011, which claims priority to Japanese Patent Application No. 2010-075972 filed on Mar. 29, 2010. The disclosures of these applications including the specifications, the drawings, and the claims are hereby incorporated by reference in their entirety.

### BACKGROUND

The present disclosure relates to power line structures of semiconductor devices.

In recent semiconductor devices, power lines are formed by using wiring layers having an increased wiring film thickness and thus having reduced wiring resistance, in order to minimize a voltage drop in the power lines. In a fine process using multilayer interconnection, a wiring layer having an increased thickness is typically formed as an upper layer. Accordingly, a plurality of stacked vias are formed which connect the power lines in the upper layer to an element to which power is to be supplied such as standard cells in a lower layer.

Japanese Patent Publication No. 2008-311570 discloses a power line structure in which an interconnect layer is interposed between power lines forming a power supply mesh and the stacked vias having wirings of one or more layers are provided between the power lines.

### SUMMARY

However, in conventional structures, stacked vias included in a power line structure block the way in the wiring direction in a wiring layer located below power lines, which reduces interconnection resources for signal lines. In the power line structure described in Japanese Patent Publication No. 2008-311570 as well, the stacked vias, which are formed between the power lines forming the power supply mesh, reduce interconnection resources for signal lines.

In order to suppress reduction in interconnection resources for signal lines, it is preferable to reduce the number of stacked vias included in the power line structure. However, reducing the number of stacked vias increases the value of combined resistance in the power line structure accordingly, and thus further increases a power supply voltage drop.

It is an object of the present disclosure to provide a semiconductor device that has a power line structure capable of securing large interconnection resources for signal lines while suppressing a power supply voltage drop.

In order to suppress a power supply voltage drop without reducing interconnection resources for signal lines, it is preferable to form a power supply strap line, which supplies a power supply potential or a substrate potential to a standard cell row, in as lower a wiring layer as possible, thereby reducing the number of layers of stacked vias from the power supply strap line to an element to which power is to be supplied.

A semiconductor device according to a first aspect of the present disclosure includes: a substrate on which a plurality of standard cell rows, each having a plurality of standard cells arranged in a first direction, are arranged in a second direction perpendicular to the first direction; first to n^{th} wiring layers (where “n” is an integer of 5 or more) which are formed on the substrate so as to be stacked in order from the substrate, and in which signal lines can be arranged; a power supply potential line and a substrate potential line which are formed in the first wiring layer and are placed between the standard cell rows or over the standard cell rows; a power supply strap line formed in the m^{th} wiring layer (where 1≦m≦n/2) and extending in the second direction; lower via portions that connect the power supply strap line to the power supply potential line and the substrate potential line; and upper via portions that connect the power supply strap line to a potential supply portion formed above the n^{th} wiring layer, wherein the upper via portions are arranged at a lower density in the second direction than the lower via portions.

According to this aspect, the power supply potential line and the substrate potential line are formed in the first wiring layer of the first to n^{th} wiring layers, and the power supply strap line is formed in the m^{th} wiring layer that is located below the center of the overall height of the wiring layers. The upper via portions that connect the power supply strap line to the potential supply portion are arranged at a lower density in the second direction, which is a direction in which the power supply strap line extends, than the lower via portions that connect the power supply strap line to the power supply potential line and the substrate potential line. This configuration can reduce the number of via portions without increasing the value of combined resistance in the power line structure. Thus, the power line structure can be implemented which is capable of securing large interconnection resources for signal lines while suppressing a power supply voltage drop.

A semiconductor device according to a second aspect of the present disclosure includes: a substrate on which a plurality of standard cell rows, each having a plurality of standard cells arranged in a first direction, are arranged in a second direction perpendicular to the first direction; first to n^{th} wiring layers (where “n” is an integer of 3 or more) which are formed on the substrate so as to be stacked in order from the substrate, and in which signal lines can be arranged; a power supply potential line and a substrate potential line which are formed in the first wiring layer and are placed between the standard cell rows or over the standard cell rows; a power supply strap line formed in the first wiring layer, extending in the second direction, and connected to the power supply potential line or the substrate potential line; and upper via portions that connect the power supply strap line to a potential supply portion formed above the n^{th} wiring layer.

According to this aspect, the power supply potential line and the substrate potential line as well as the power supply strap line are formed in the first wiring layer of the first to n^{th} wiring layers. The upper via portions are formed which connect the power supply strap line to the potential supply portion. This configuration can reduce the number of upper via portions without increasing the value of the combined resistance in the power line structure. Thus, the power line structure can be implemented which is capable of securing large interconnection resources for signal lines while suppressing a power supply voltage drop.

A semiconductor device according to a third aspect of the present disclosure includes: a substrate on which a plurality of standard cell rows, each having a plurality of standard cells arranged in a first direction, are arranged in a second direction perpendicular to the first direction; first to n^{th} wiring layers (where “n” is an integer of 5 or more) which are formed on the substrate so as to be stacked in order from the substrate, and in which signal lines can be arranged; a power supply potential line and a substrate potential line which are formed in the second wiring layer and are placed between the standard cell rows or over the standard cell rows; a power supply strap line formed in the first wiring layer and extending in the second direction; lower via portions that connect the power supply strap line to the power supply potential line and the substrate potential line; and upper via portions that connect the power supply potential line and the substrate potential line to a potential supply portion formed above the n^{th} wiring layer, wherein the upper via portions are arranged at a lower density in the second direction than the lower via portions.

According to this aspect, the power supply potential line and the substrate potential line are formed in the second wiring layer of the first to n^{th} wiring layers, and the power supply strap line is formed in the first wiring layer located below the second wiring layer. The upper via portions that connect the power supply potential line and the substrate potential line to the potential supply portion are arranged at a lower density in the second direction, which is a direction in which the power supply strap line extends, than the lower via portions that connect the power supply strap line to the power supply potential line and the substrate potential line. This configuration can reduce the number of via portions without increasing the value of combined resistance in the power line structure. Thus, the power line structure can be implemented which is capable of securing large interconnection resources for signal lines while suppressing a power supply voltage drop.

According to the present disclosure, a power line structure can be implemented which is capable of securing large interconnection resources for signal lines while suppressing a power supply voltage drop.

### BRIEF DESCRIPTION OF THE DRAWINGS

FIG. 1 is a plan view showing the configuration of a semiconductor device according to a first embodiment.

FIGS. 2A-2B are cross-sectional views showing the configuration of the semiconductor device according to the first embodiment.

FIG. 3 is a diagram showing the configuration of standard cells arranged in a semiconductor device according to each embodiment.

FIG. 4 is a plan view showing the configuration of a semiconductor device according to a second embodiment.

FIGS. 5A-5B are cross-sectional views showing the configuration of the semiconductor device according to the second embodiment.

FIG. 6 is a plan view showing the configuration of a semiconductor device according to a third embodiment.

FIGS. 7A-7B are cross-sectional views showing the configuration of the semiconductor device according to the third embodiment.

FIG. 8 is a plan view showing the configuration of a semiconductor device according to a fourth embodiment.

FIGS. 9A-9B are cross-sectional views showing the configuration of the semiconductor device according to the fourth embodiment.

FIG. 10 is a plan view showing the configuration of a semiconductor device according to a fifth embodiment.

FIGS. 11A-11B are cross-sectional views showing the configuration of the semiconductor device according to the fifth embodiment.

FIGS. 12A-12C are diagrams showing the configuration of a semiconductor device according to a comparative example.

FIGS. 13A-13B are diagrams showing calculation models of power line resistance.

### DETAILED DESCRIPTION

Semiconductor devices according to embodiments of the present disclosure will be described below with reference to the accompanying drawings.

### First Embodiment

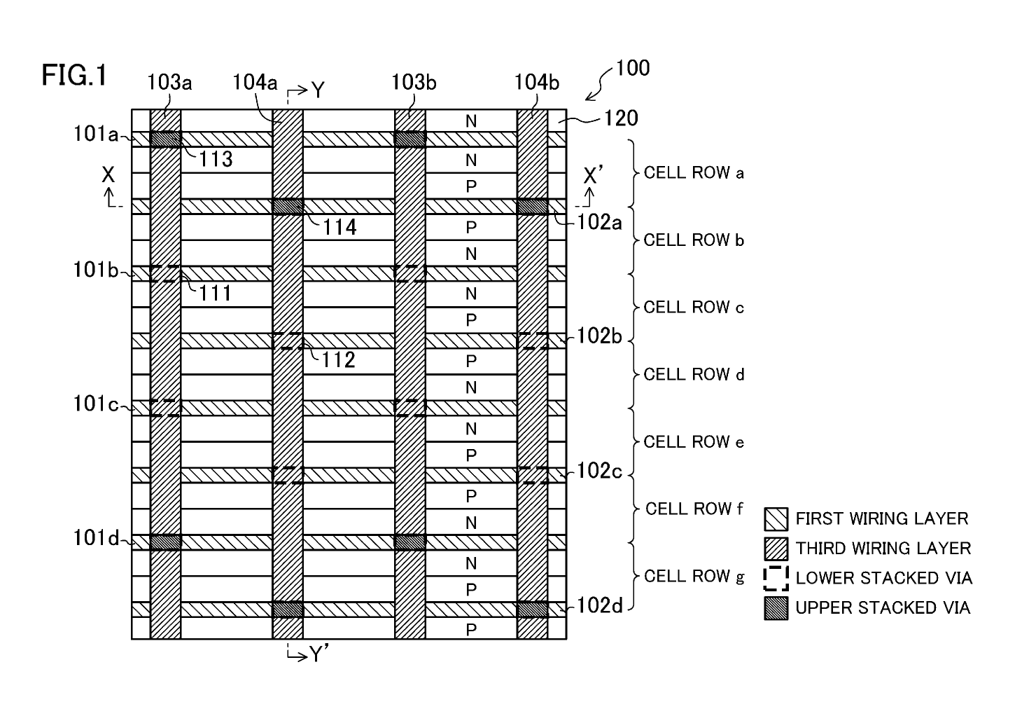

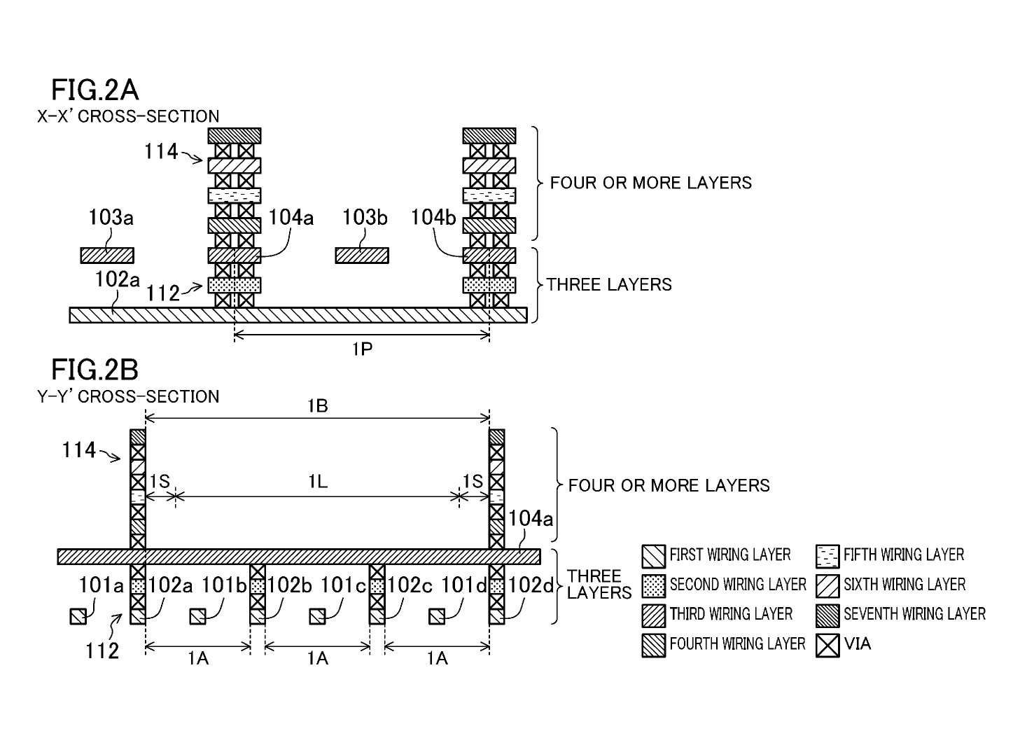

FIG. 1 is a plan view (a simplified diagram of a layout pattern) showing the configuration of a semiconductor device according to a first embodiment. FIG. 2A is a cross-sectional view taken along line X-X′ in FIG. 1, and FIG. 2B is a cross-sectional view taken along line Y-Y′ in FIG. 1. Although the structure located below a first wiring layer is not shown in FIGS. 1 and 2A-2B for simplification, the semiconductor device is structured so that power is supplied from the first wiring layer to the sources or wells of transistors, diodes, capacitive elements, etc. via vias etc. The same applies to the following configuration diagrams of the semiconductor device.

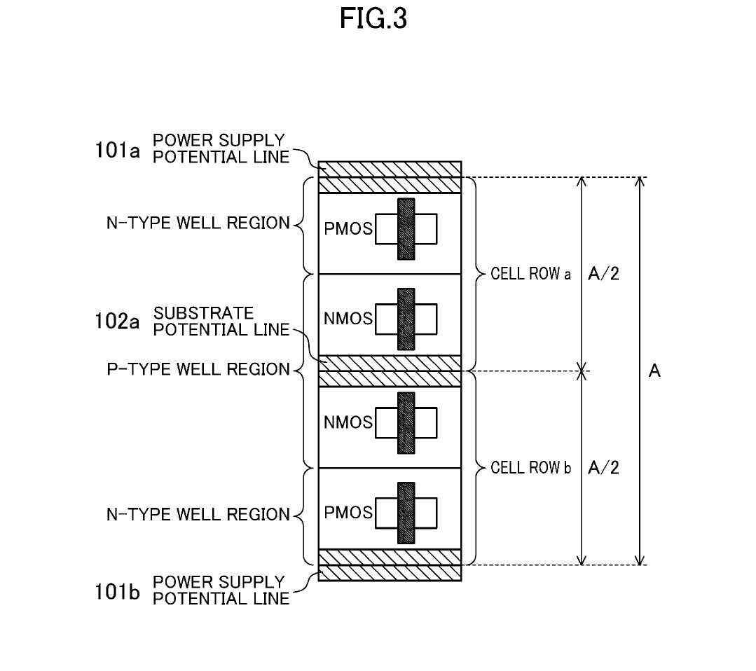

In a semiconductor device 100 shown in FIGS. 1 and 2A-2B, a plurality of standard cell rows (cell rows “a” to “g”) are arranged on a substrate 120 in a vertical direction (a second direction) in FIG. 1. A plurality of standard cells are arranged in a horizontal direction (a first direction) in FIG. 1 in each standard cell row. FIG. 3 schematically shows the configuration of the standard cells. The two standard cells shown in FIG. 3 are included in the cell rows “a,” “b,” respectively, and each standard cell has an N-type well region where a P-type metal oxide semiconductor (PMOS) transistor is formed, and a P-type well region where an N-type metal oxide semiconductor (NMOS) transistor is formed. Although each standard cell is configured to include one PMOS transistor and one NMOS transistor in FIG. 3, the actual standard cells have various internal configurations.

The semiconductor device 100 has seven or more wiring layers on the substrate 120. In the configuration of FIG. 2, first to seventh wiring layers are stacked in order from the substrate 120. Signal lines in the first wiring layer are mainly used for connection between elements in the standard cell, and signal lines in the second to seventh wiring layers are mainly used for connection between the standard cells. Preferential wiring directions of the second, fourth, and sixth wiring layers are the horizontal direction in FIG. 1, and preferential wiring directions of the third, fifth, and seventh wiring layers are the vertical direction in FIG. 1.

In the present embodiment and the following embodiments, the term “wiring layer” refers to a wiring layer in which a signal line can be placed, and does not include a wiring layer in which no signal line can be placed.

Power supply potential lines 101a, 101b, 101c, 101d and substrate potential lines 102a, 102b, 102c, 102d, each placed between corresponding adjoining ones of the standard cell rows, are formed in the first wiring layer. The power supply potential lines 101a, 101b, 101c, 101d apply a power supply potential to the standard cell rows connected thereto, and the substrate potential lines 102a, 102b, 102c, 102d apply a substrate potential to the standard cell rows connected thereto.

Power supply strap lines 103a, 103b configured to supply the power supply potential and power supply strap lines 104a, 104b configured to supply the substrate potential are arranged parallel to each other in the third wiring layer so as to extend in the vertical direction in FIG. 1. The power supply strap lines 103a, 103b are connected to the power supply potential lines 101a, 101b, 101c, 101d via lower stacked vias 111 as lower via portions. Similarly, the power supply strap lines 104a, 104b are connected to the substrate potential lines 102a, 102b, 102c, 102d via lower stacked vias 112 as lower via portions. Each of the lower stacked vias 111, 112 is formed by vias between the first and second wiring layers and between the second and third wiring layers, and a short wiring in the second wiring layer.

The power supply strap lines 103a, 103b are connected via upper stacked vias 113 as upper via portions to a potential supply portion (not shown) which is formed above the seventh wiring layer and to which the power supply potential is supplied. Similarly, the power supply strap lines 104a, 104b are connected via upper stacked vias 114 as upper via portions to a potential supply portion (not shown) which is formed above the seventh wiring layer and to which the substrate potential is supplied. Each of the upper stacked vias 113, 114 is formed by vias between the third and fourth wiring layers, between the fourth and fifth wiring layers, between the fifth and sixth wiring layers, and between the sixth and seventh wiring layers, and short wirings in the fourth, fifth, sixth, and seventh wiring layers.

As shown in FIG. 2B, the lower stacked vias 112 are substantially regularly arranged at intervals of 1A, and the upper stacked vias 114 are substantially regularly arranged at intervals of 1B. The interval 1A is substantially equal to the height A of the two standard cells shown in FIG. 3. The interval 1B is larger than the interval 1A, and in this example, is about 3 times the interval 1A. That is, the upper stacked vias 114 are arranged at a lower density than the lower stacked vias 112 in the vertical direction (the second direction) in FIG. 1. Similarly, the upper stacked vias 113 are arranged at a lower density than the lower stacked vias 111 in the vertical direction (the second direction) in FIG. 1. In FIG. 2B, “1L” represents a range in the fifth wiring layer which can be used as interconnection resources for signal lines, and “1S” represents the distance from the upper stacked via 114 to the range 1L.

In the semiconductor device 100 according to the present embodiment, the power supply strap lines are formed in the third wiring layer of the seven or more wiring layers. That is, the power line structure of the present embodiment has three wiring layers from the power supply strap lines to the standard cell rows, and four or more wiring layers above the power supply strap lines. This configuration can reduce the number of lower stacked vias from the power supply strap lines to the standard cell rows, and thus can suppress reduction in interconnection resources for signal lines.

Since no wiring layer whose preferential wiring direction is the vertical direction in FIG. 1 is provided below the third wiring layer in which the power supply strap lines are formed, the influence of reduction in interconnection resources for signal lines which is caused by providing the lower stacked vias is limited.

Moreover, in the power line structure of the present embodiment, the wiring direction in the wiring layers located above the third wiring layer in which the power supply strap lines are formed is not limited by the direction in which the power lines are arranged. This allows the wiring layers located above the third wiring layer to have any preferential wiring direction as necessary.

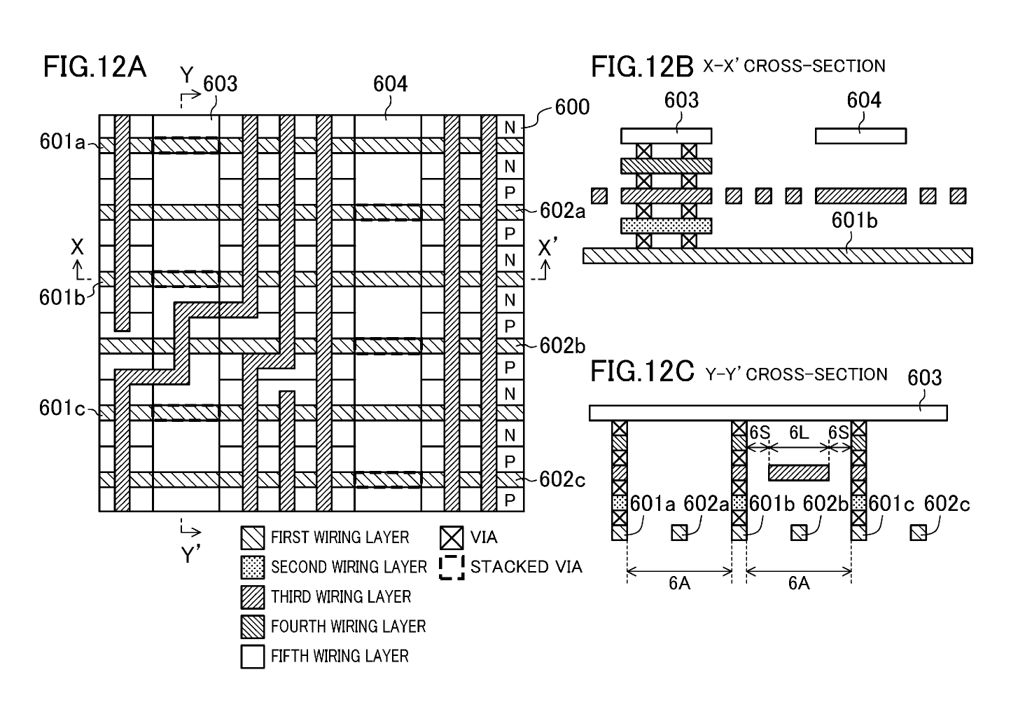

FIGS. 12A-12C are diagrams showing the configuration of a semiconductor device as a comparative example. FIG. 12A is a plan view, FIG. 12B is a cross-sectional view taken along line X-X′ in FIG. 12A, and FIG. 12C is a cross-sectional view taken along line Y-Y′in FIG. 12A. The semiconductor device of FIGS. 12A-12C has five wiring layers, and power supply strap lines 603, 604 are formed in the fifth wiring layer as the uppermost wiring layer. The power supply strap line 603 is connected via stacked vias to power supply potential lines 601a, 601b, 601c formed in the first wiring layer, and the power supply strap line 604 is connected via stacked vias to substrate potential lines 602a, 602b, 602c formed in the first wiring layer. In FIG. 12C, “6A” represents the interval between the stacked vias, “6L” represents a range in which the signal lines can be arranged between the stack vias, and “6S” represents the distance from the stack via to the range 6L.

In typical standard cell semiconductor devices, the interval 6A is slightly less than about twice the height of the standard cell, and the range 6L in which the signal lines can be arranged is very small. That is, the stacked vias block the way in the wiring direction in the wiring layer whose preferential wiring direction is the same as the direction in which the power supply strap lines extend, such as the third wiring layer. This significantly reduces the rate of utilization of this wiring layer as the signal lines, and thus significantly reduces the effective interconnection resources for signal lines.

On the other hand, in the present embodiment, the lower stacked vias basically do not block the way in the wiring direction in the wiring layers located below the power supply strap lines. Moreover, since the upper stacked vias are arranged at a lower density in the wiring layers located above the power supply strap lines, reduction in interconnection resources for signal lines is greatly suppressed.

In the above comparative example, when the interval between the power supply strap lines is sufficiently large, reduction in interconnection resources for signal lines, which is caused by the stacked vias blocking the way in the wiring direction, is not very large. However, if the interval between the power supply strap lines is small, the interconnection resources for signal lines are significantly reduced. That is, advantages of the present embodiment can be more significantly obtained as the interval between the power supply strap lines decreases. For example, the advantages of the present embodiment are significant when the interval between the power supply strap lines is 20 μm or less.

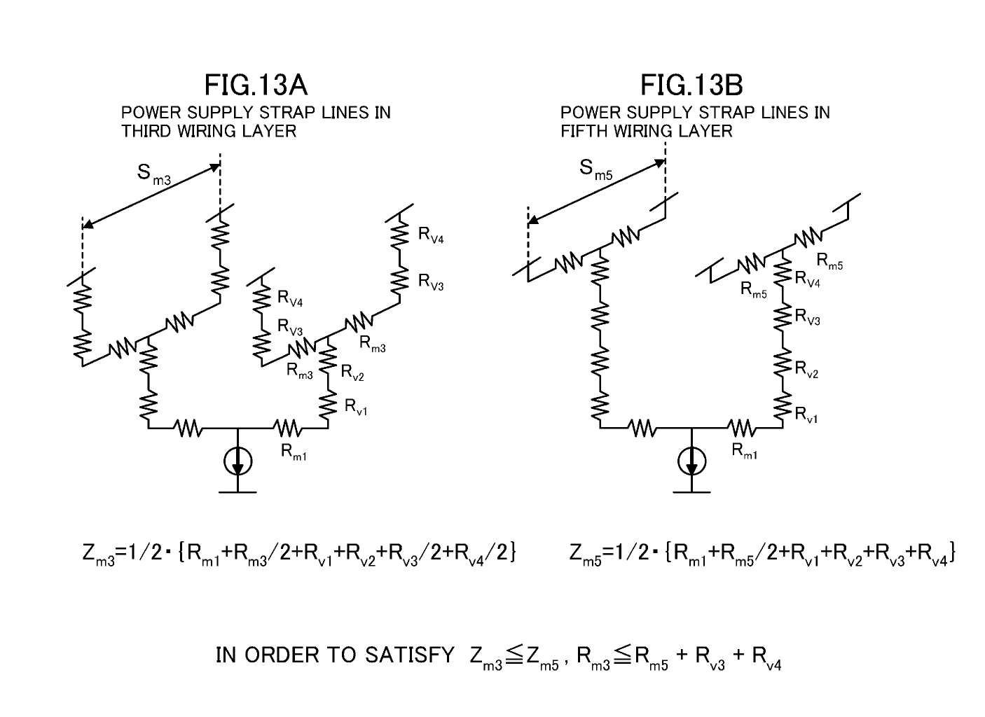

Characteristics of a power supply voltage drop will be described below with reference to FIGS. 13A-13B. FIGS. 13A-13B show calculation models of combined resistance of a power line structure in a semiconductor device having five wiring layers. FIG. 13A shows an example in which power supply strap lines are formed in the third wiring layer, and FIG. 13B shows an example in which power supply strap lines are formed in the fifth wiring layer. “Rₘ₁,” “Rₘ₃,” and “Rₘ₅” represent the resistance values of the first, third, and fifth wiring layers, respectively, and “Rᵥ₁,” “Rᵥ₂,” “Rᵥ₃,” and “Rᵥ₄” represent the resistance values of vias that connect the first and the second wiring layers, that connect the second and third wiring layers, that connect the third and fourth wiring layers, and that connect the fourth and fifth wiring layers, respectively. “Sₘ₃” represents the interval at which power is supplied from a potential supply portion to the power supply strap lines formed in the third wiring layer, and “Sₘ₅” represents the interval at which power is supplied from the potential supply portion to the power supply strap lines formed in the fifth wiring layer.

Combined resistance Zₘ₃ in the example of FIG. 13A and combined resistance Zₘ₅ in the example of FIG. 13B are represented by the expressions shown in FIGS. 13A-13B. As can be seen from these expressions, if the power supply interval Sₘ₃ is equal to the power supply interval Sₘ₅ and the wiring resistance Rₘ₃ is equal to the wiring resistance Rₘ₅, the combined resistance Zₘ₃ is lower than the combined resistance Zₘ₅ by “Rᵥ₃ Rᵥ₄.” That is, the combined resistance of the power line structure is lower in the case where the power supply strap lines are formed in the third wiring layer than in the case where the power supply strap lines are formed in the fifth wiring layer.

If the combined resistance Zₘ₃ is allowed to have about the same value as the combined resistance Zₘ₅, the wiring resistance Rₘ₃ can be increased to “Rₘ₅+Rᵥ₃+Rᵥ₄.” Thus, the power supply interval S can be made longer than the power supply interval Sₘ₅. That is, as in the semiconductor device of the present embodiment, the interval between the upper stacked vias can be increased without increasing the combined resistance of the power line structure. Thus, reduction in interconnection resources for signal lines can be suppressed while suppressing a power supply voltage drop.

That is, according to the present embodiment, the power supply potential lines and the substrate potential lines are formed in the first wiring layer, and the power supply strap lines are formed in the third wiring layer that is located below the center of the overall height of the wiring layers. The upper via portions that connect the power supply strap lines to the potential supply portion are arranged at a lower density in the direction in which the power supply strap lines extend than the lower via portions that connect the power supply strap lines to the power supply potential lines and the substrate potential lines. This configuration can reduce the number of via portions without increasing the value of the combined resistance in the power line structure. Thus, the power line structure can be implemented which is capable of securing large interconnection resources for signal lines while suppressing a power supply voltage drop.

### Second Embodiment

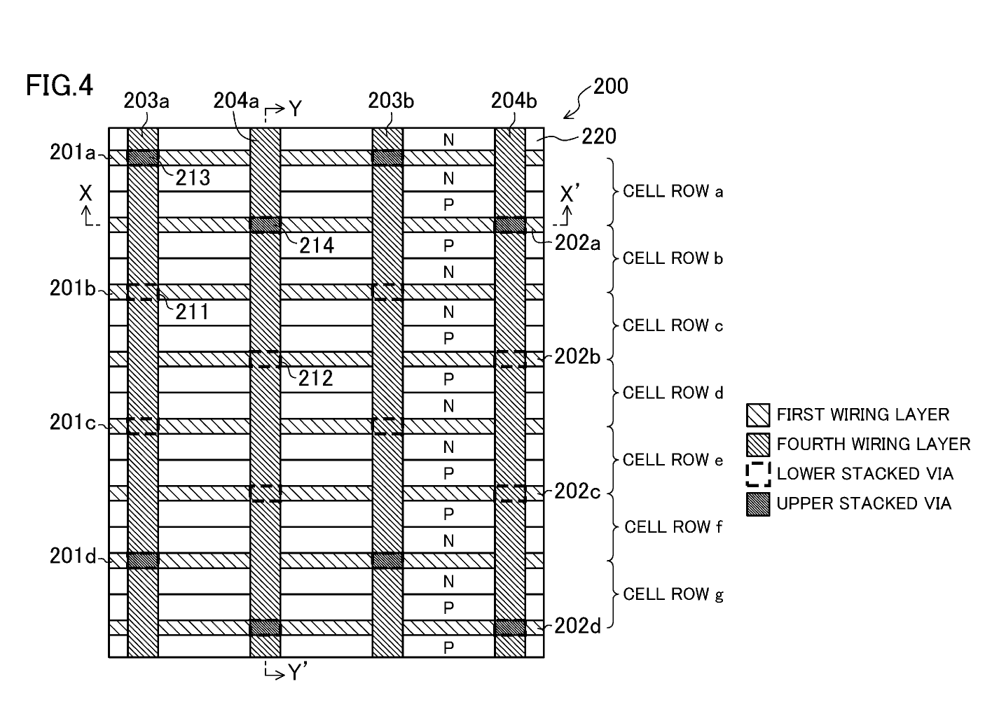

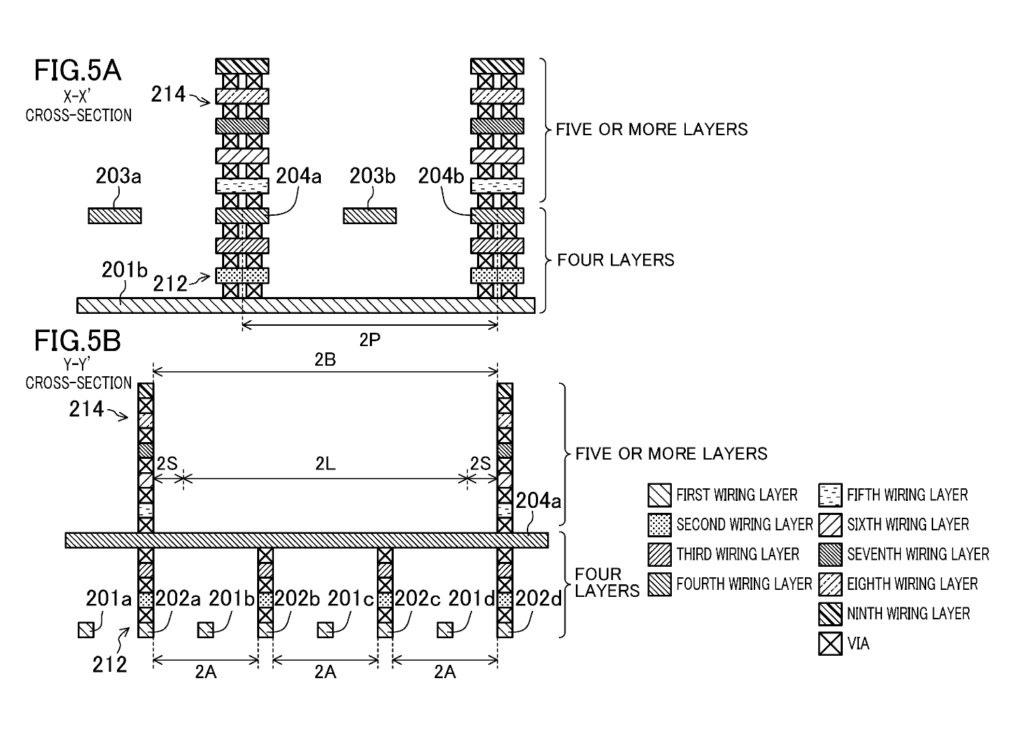

FIG. 4 is a plan view (a simplified diagram of a layout pattern) showing the configuration of a semiconductor device according to a second embodiment. FIG. 5A is a cross-sectional view taken along line X-X′ in FIG. 4, and FIG. 5B is a cross-sectional view taken along line Y-Y′ in FIG. 4. In a semiconductor device 200 shown in FIGS. 4 and 5A-5B, a plurality of standard cell rows (cell rows “a” to “g”) are arranged on a substrate 220 in a vertical direction (a second direction) in FIG. 4. A plurality of standard cells are arranged in a horizontal direction (a first direction) in FIG. 4 in each standard cell row.

The semiconductor device 200 has nine or more wiring layers on the substrate 220. In the configuration of FIGS. 5A-5B, first to ninth wiring layers are stacked in order from the substrate 220. Signal lines in the first wiring layer are mainly used for connection between elements in the standard cell, and signal lines in the second to ninth wiring layers are mainly used for connection between the standard cells. Preferential wiring directions of the third, fifth, seventh, and ninth wiring layers are the horizontal direction in FIG. 4, and preferential wiring directions of the second, fourth, sixth, and eighth wiring layers are the vertical direction in FIG. 4.

Power supply potential lines 201a, 201b, 201c, 201d and substrate potential lines 202a, 202b, 202c, 202d, each placed between corresponding adjoining ones of the standard cell rows, are formed in the first wiring layer. The power supply potential lines 201a, 201b, 201c, 201d apply a power supply potential to the standard cell rows connected thereto, and the substrate potential lines 202a, 202b, 202c, 202d apply a substrate potential to the standard cell rows connected thereto.

Power supply strap lines 203a, 203b configured to supply the power supply potential and power supply strap lines 204a, 204b configured to supply the substrate potential are arranged parallel to each other in the fourth wiring layer so as to extend in the vertical direction in FIG. 4. The power supply strap lines 203a, 203b are connected to the power supply potential lines 201a, 201b, 201c, 201d via lower stacked vias 211 as lower via portions. Similarly, the power supply strap lines 204a, 204b are connected to the substrate potential lines 202a, 202b, 202c, 202d via lower stacked vias 212 as lower via portions. Each of the lower stacked vias 211, 212 is formed by vias between the first and second wiring layers, between the second and third wiring layers, and between the third and fourth wiring layers, and short wirings in the second and third wiring layers.

The power supply strap lines 203a, 203b are connected via upper stacked vias 213 as upper via portions to a potential supply portion (not shown) which is formed above the ninth wiring layer and to which the power supply potential is supplied. Similarly, the power supply strap lines 204a, 204b are connected via upper stacked vias 214 as upper via portions to a potential supply portion (not shown) which is formed above the ninth wiring layer and to which the substrate potential is supplied. Each of the upper stacked vias 213, 214 is formed by vias between the fourth and fifth wiring layers, between the fifth and sixth wiring layers, between the sixth and seventh wiring layers, between the seventh and eighth wiring layers, and between the eighth and ninth wiring layers, and short wirings in the fifth, sixth, seventh, eighth, and ninth wiring layers.

As shown in FIG. 5B, the lower stacked vias 212 are substantially regularly arranged at intervals of 2A, and the upper stacked vias 214 are substantially regularly arranged at intervals of 2B. The interval 2A is substantially equal to the height A of the two standard cells shown in FIG. 3. The interval 2B is larger than the interval 2A, and in this example, is about 3 times the interval 2A. That is, the upper stacked vias 214 are arranged at a lower density than the lower stacked vias 212 in the vertical direction (the second direction) in FIG. 4. Similarly, the upper stacked vias 213 are arranged at a lower density than the lower stacked vias 211 in the vertical direction (the second direction) in FIG. 4. In FIG. 5B, “2L” represents a range in the sixth wiring layer which can be used as interconnection resources for signal lines, and “2S” represents the distance from the upper stacked via 214 to the range 2L.

In the semiconductor device 200 according to the present embodiment, the power supply strap lines are formed in the fourth wiring layer of the nine or more wiring layers. That is, the power line structure of the present embodiment has four wiring layers from the power supply strap lines to the standard cell rows, and five or more wiring layers above the power supply strap lines. This configuration can reduce the number of lower stacked vias from the power supply strap lines to the standard cell rows, and thus can suppress reduction in interconnection resources for signal lines.

Moreover, in the power line structure of the present embodiment, the wiring direction in the wiring layers located above the fourth wiring layer in which the power supply strap lines are formed is not limited by the direction in which the power lines are arranged. This allows the wiring layers located above the fourth wiring layer to have any preferential wiring direction as necessary.

That is, according to the present embodiment, the power supply potential lines and the substrate potential lines are formed in the first wiring layer, and the power supply strap lines are formed in the fourth wiring layer that is located below the center of the overall height of the wiring layers. The upper via portions that connect the power supply strap lines to the potential supply portion are arranged at a lower density in the direction in which the power supply strap lines extend than the lower via portions that connect the power supply strap lines to the power supply potential lines and the substrate potential lines. This configuration can reduce the number of via portions without increasing the value of the combined resistance in the power line structure. Thus, the power line structure can be implemented which is capable of securing large interconnection resources for signal lines while suppressing a power supply voltage drop.

### Third Embodiment

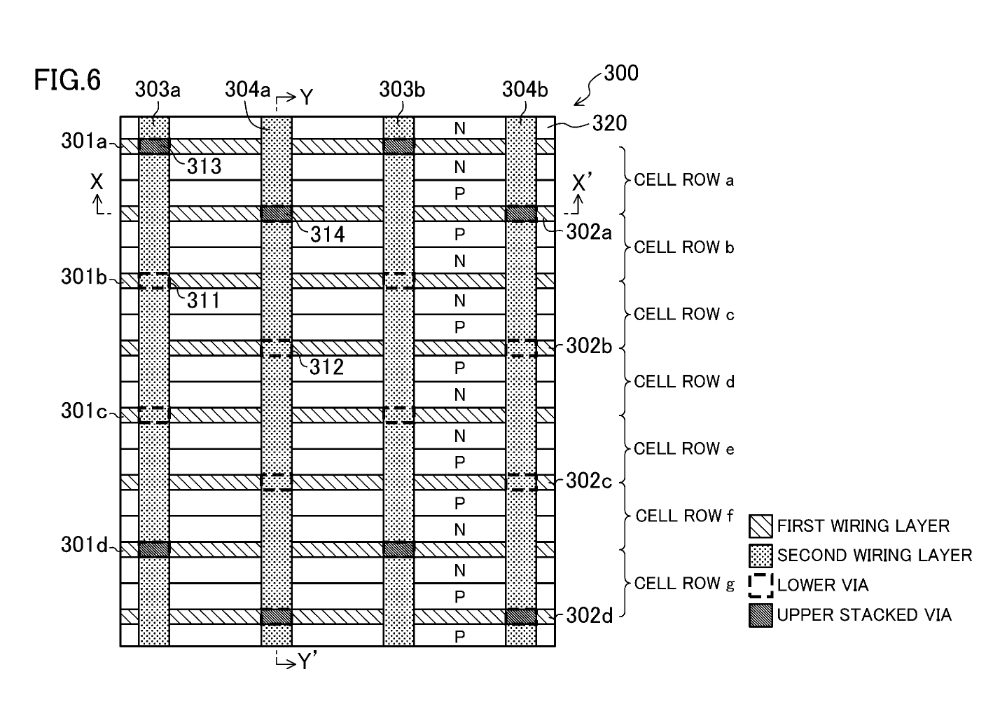

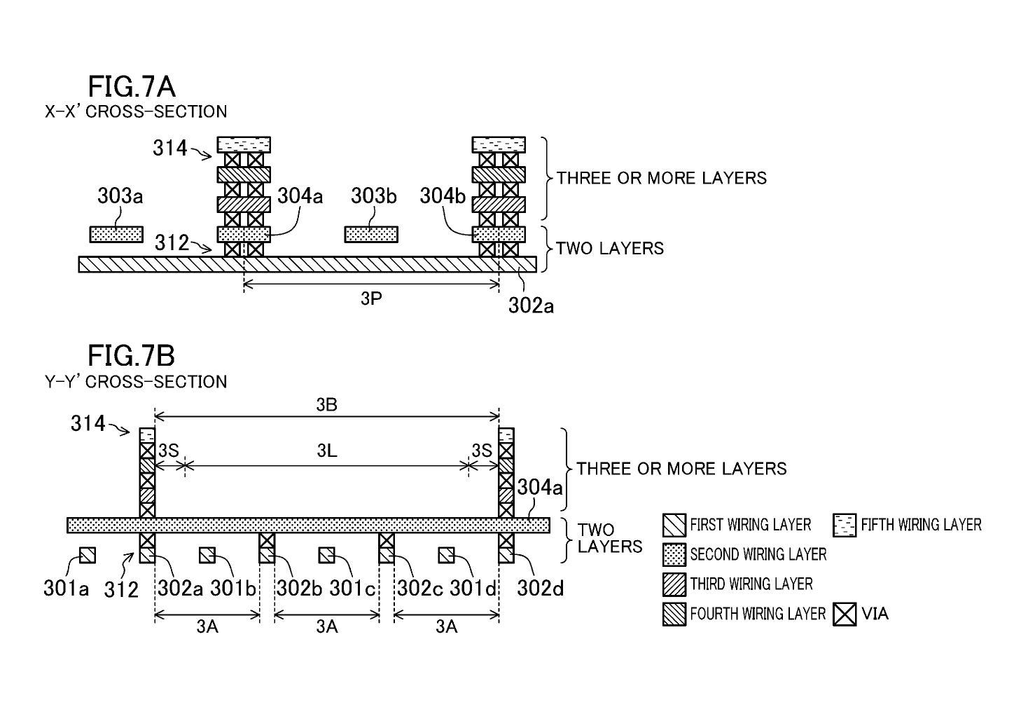

FIG. 6 is a plan view (a simplified diagram of a layout pattern) showing the configuration of a semiconductor device according to a third embodiment. FIG. 7A is a cross-sectional view taken along line X-X′ in FIG. 6, and FIG. 7B is a cross-sectional view taken along line Y-Y′ in FIG. 6. In a semiconductor device 300 shown in FIGS. 6 and 7A-7B, a plurality of standard cell rows (cell rows “a” to “g”) are arranged on a substrate 320 in a vertical direction (a second direction) in FIG. 6. A plurality of standard cells are arranged in a horizontal direction (a first direction) in FIG. 6 in each standard cell row.

The semiconductor device 300 has five or more wiring layers on the substrate 320. In the configuration of FIGS. 7A-7B, first to fifth wiring layers are stacked in order from the substrate 320. Signal lines in the first wiring layer are mainly used for connection between elements in the standard cell, and signal lines in the second to fifth wiring layers are mainly used for connection between the standard cells. Preferential wiring directions of the third and fifth wiring layers are the horizontal direction in FIG. 6, and preferential wiring directions of the second and fourth wiring layers are the vertical direction in FIG. 6.

Power supply potential lines 301a, 301b, 301c, 301d and substrate potential lines 302a, 302b, 302c, 302d, each placed between corresponding adjoining ones of the standard cell rows, are formed in the first wiring layer. The power supply potential lines 301a, 301b, 301c, 301d apply a power supply potential to the standard cell rows connected thereto, and the substrate potential lines 302a, 302b, 302c, 302d apply a substrate potential to the standard cell rows connected thereto.

Power supply strap lines 303a, 303b configured to supply the power supply potential and power supply strap lines 304a, 304b configured to supply the substrate potential are arranged parallel to each other in the second wiring layer so as to extend in the vertical direction in FIG. 6. The power supply strap lines 303a, 303b are connected to the power supply potential lines 301a, 301b, 301c, 301d via lower vias 311 as lower via portions. Similarly, the power supply strap lines 304a, 304b are connected to the substrate potential lines 302a, 302b, 302c, 302d via lower vias 312 as lower via portions. Each of the lower vias 311, 312 is a via between the first and second wiring layers.

The power supply strap lines 303a, 303b are connected via upper stacked vias 313 as upper via portions to a potential supply portion (not shown) which is formed above the fifth wiring layer and to which the power supply potential is supplied. Similarly, the power supply strap lines 304a, 304b are connected via upper stacked vias 314 as upper via portions to a potential supply portion (not shown) which is formed above the fifth wiring layer and to which the substrate potential is supplied. Each of the upper stacked vias 313, 314 is formed by vias between the second and third wiring layers, between the third and fourth wiring layers, and between the fourth and fifth wiring layers, and short wirings in the third, fourth, and fifth wiring layers.

As shown in FIG. 7B, the lower vias 312 are substantially regularly arranged at intervals of 3A, and the upper stacked vias 314 are substantially regularly arranged at intervals of 3B. The interval 3A is substantially equal to the height A of the two standard cells shown in FIG. 3. The interval 3B is larger than the interval 3A, and in this example, is about 3 times the interval 3A. That is, the upper stacked vias 314 are arranged at a lower density than the lower vias 312 in the vertical direction (the second direction) in FIG. 6. Similarly, the upper stacked vias 313 are arranged at a lower density than the lower vias 311 in the vertical direction (the second direction) in FIG. 6. In FIG. 7B, “3L” represents a range in the fourth wiring layer which can be used as interconnection resources for signal lines, and “3S” represents the distance from the upper stacked via 314 to the range 3L.

In the semiconductor device 300 according to the present embodiment, the power supply strap lines are formed in the second wiring layer of the five or more wiring layers. That is, the power line structure of the present embodiment has two wiring layers from the power supply strap lines to the standard cell rows, and three or more wiring layers above the power supply strap lines. This configuration can reduce the number of lower vias from the power supply strap lines to the standard cell rows, and thus can suppress reduction in interconnection resources for signal lines.

In the power line structure of the present embodiment, the wiring direction in the wiring layers located above the second wiring layer in which the power supply strap lines are formed is not limited by the direction in which the power lines are arranged. This allows the wiring layers located above the second wiring layer to have any preferential wiring direction as necessary.

That is, according to the present embodiment, the power supply potential lines and the substrate potential lines are formed in the first wiring layer, and the power supply strap lines are formed in the second wiring layer that is located below the center of the overall height of the wiring layers. The upper via portions that connect the power supply strap lines to the potential supply portion are arranged at a lower density in the direction in which the power supply strap lines extend than the lower via portions that connect the power supply strap lines to the power supply potential lines and the substrate potential lines. This configuration can reduce the number of via portions without increasing the value of the combined resistance in the power line structure. Thus, the power line structure can be implemented which is capable of securing large interconnection resources for signal lines while suppressing a power supply voltage drop.

In the first to third embodiments, the upper via portions are arranged at a density that is about ⅓ of that of the lower via portions. However, the present disclosure is not limited to this. For example, advantages of the present disclosure can be sufficiently obtained if the upper via portions are arranged at a density that is equal to or less than ½ of that of the lower via portions.

In the first to third embodiments, the upper via portions are positioned so as to overlap the lower via portions as viewed in the direction perpendicular to the substrate surface. However, the present disclosure is not limited to this.

In the first to third embodiments, adjoining ones of the standard cell rows have a common power supply potential line or a common substrate potential line. However, each standard cell row may have its own power supply potential line and its own substrate potential line. Alternatively, the power supply potential lines and the substrate potential lines may be arranged over the standard cell rows.

In the first to third embodiments, another wiring layer may be provided between the substrate and the first wiring layer in which the power supply potential lines and the substrate potential lines are formed. Another wiring layer may be provided above the seventh wiring layer in the first embodiment, above the ninth wiring layer in the second embodiment, and above the fifth wiring layer in the third embodiment.

In the first to third embodiments, the wiring width of the power supply strap line is normally equal to or less than five times the minimum wiring width of the corresponding wiring layer, namely the third, fourth, or second wiring layer, in a region that is actually used (a region that substantially contributes to power supply).

### Fourth Embodiment

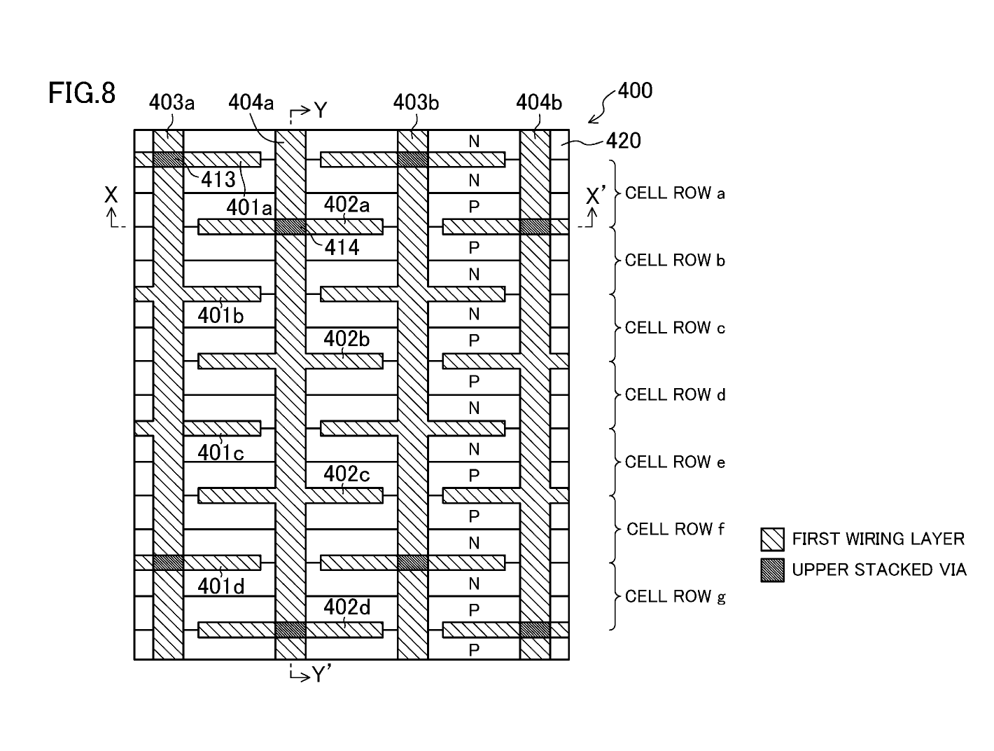

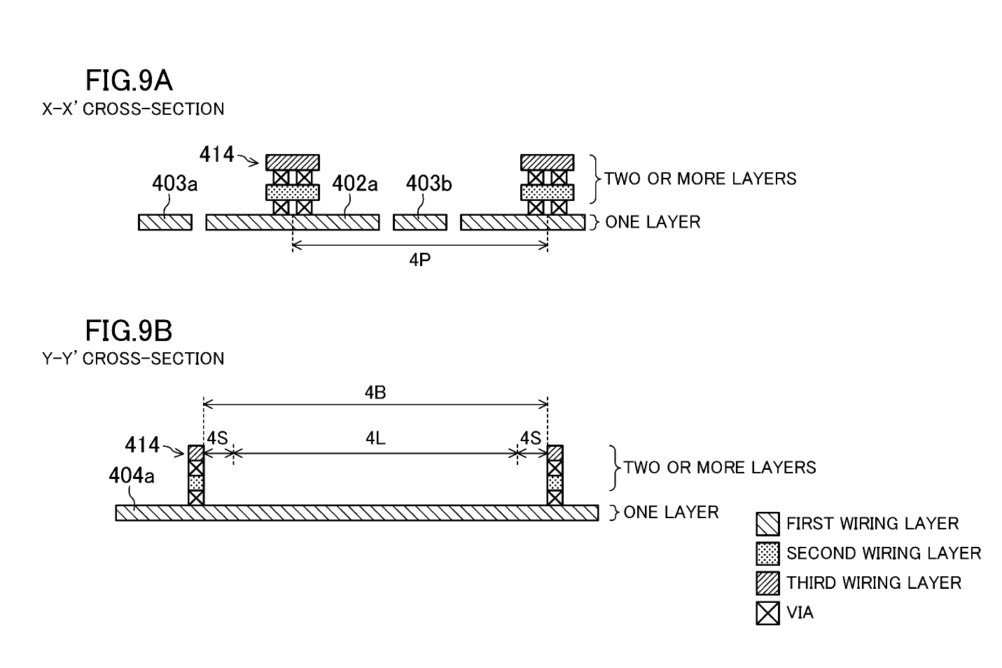

FIG. 8 is a plan view (a simplified diagram of a layout pattern) showing the configuration of a semiconductor device according to a fourth embodiment. FIG. 9A is a cross-sectional view taken along line X-X′ in FIG. 8, and FIG. 9B is a cross-sectional view taken along line Y-Y′ in FIG. 8. In a semiconductor device 400 shown in FIGS. 8 and 9A-9B, a plurality of standard cell rows (cell rows “a” to “g”) are arranged on a substrate 420 in a vertical direction (a second direction) in FIG. 8. A plurality of standard cells are arranged in a horizontal direction (a first direction) in FIG. 8 in each standard cell row.

The semiconductor device 400 has three or more wiring layers on the substrate 420. In the configuration of FIGS. 9A-9B, first to third wiring layers are stacked in order from the substrate 420. Signal lines in the first wiring layer are mainly used for connection between elements in the standard cell, and signal lines in the second and third wiring layers are mainly used for connection between the standard cells.

Power supply potential lines 401a, 401b, 401c, 401d and substrate potential lines 402a, 402b, 402c, 402d, each placed between corresponding adjoining ones of the standard cell rows, are formed in the first wiring layer. The power supply potential lines 401a, 401b, 401c, 401d apply a power supply potential to the standard cell rows connected thereto, and the substrate potential lines 402a, 402b, 402c, 402d apply a substrate potential to the standard cell rows connected thereto.

Power supply strap lines 403a, 403b configured to supply the power supply potential and power supply strap lines 404a, 404b configured to supply the substrate potential are arranged parallel to each other in the first wiring layer so as to extend in the vertical direction in FIG. 8. The power supply strap lines 403a, 403b are connected to and unified with the power supply potential lines 401a, 401b, 401c, 401d. Similarly, the power supply strap lines 404a, 404b are connected to and unified with the substrate potential lines 402a, 402b, 402c, 402d.

The power supply strap lines 403a, 403b are connected via upper stacked vias 413 as upper via portions to a potential supply portion (not shown) which is formed above the third wiring layer and to which the power supply potential is supplied. Similarly, the power supply strap lines 404a, 404b are connected via upper stacked vias 414 as upper via portions to a potential supply portion (not shown) which is formed above the third wiring layer and to which the substrate potential is supplied. Each of the upper stacked vias 413, 414 is formed by vias between the first and second wiring layers and between the second and third wiring layers, and short wirings in the second and third wiring layers.

As shown in FIG. 9B, the upper stacked vias 414 are substantially regularly arranged at intervals of 4B. The upper stacked vias 413 are arranged in a manner similar to that of the upper stacked vias 414. In FIG. 9B, “4L” represents a range in the third wiring layer which can be used as interconnection resources for signal lines, and “4S” represents the distance from the upper stacked via 414 to the range 4L.

In the semiconductor device 400 according to the present embodiment, the power supply strap lines are formed in the first wiring layer of the three or more wiring layers. That is, the power line structure of the present embodiment has one wiring layer from the power supply strap lines to the standard cell rows, and two or more wiring layers above the power supply strap lines. This configuration can suppress reduction in interconnection resources for signal lines because no lower stacked via is required from the power supply strap lines to the standard cell rows.

In the power line structure of the present embodiment, the wiring direction in the wiring layers located above the first wiring layer in which the power supply strap lines are formed is not limited by the direction in which the power lines are arranged. This allows the wiring layers located above the first wiring layer to have any preferential wiring direction as necessary.

That is, according to the present embodiment, the power supply potential lines and the substrate potential lines as well as the power supply strap lines are formed in the first wiring layer. The upper via portions are formed which connect the power supply strap lines to the potential supply portion. This configuration can reduce the number of upper via portions without increasing the value of the combined resistance in the power line structure. Thus, the power line structure can be implemented which is capable of securing large interconnection resources for signal lines while suppressing a power supply voltage drop.

In the present embodiment, adjoining ones of the standard cell rows have common power supply potential lines or common substrate potential lines. However, each standard cell row may have its own power supply potential line and its own substrate potential line. Alternatively, the power supply potential lines and the substrate potential lines may be arranged over the standard cell rows.

In the present embodiment, another wiring layer may be provided between the substrate and the first wiring layer in which the power supply potential lines and the substrate potential lines are formed. Another wiring layer may be provided above the third wiring layer.

In the present embodiment, the wiring width of the power supply strap line is normally equal to or less than five times the minimum wiring width of the corresponding wiring layer, namely the first wiring layer, in a region that is actually used (a region that substantially contributes to power supply).

### Fifth Embodiment

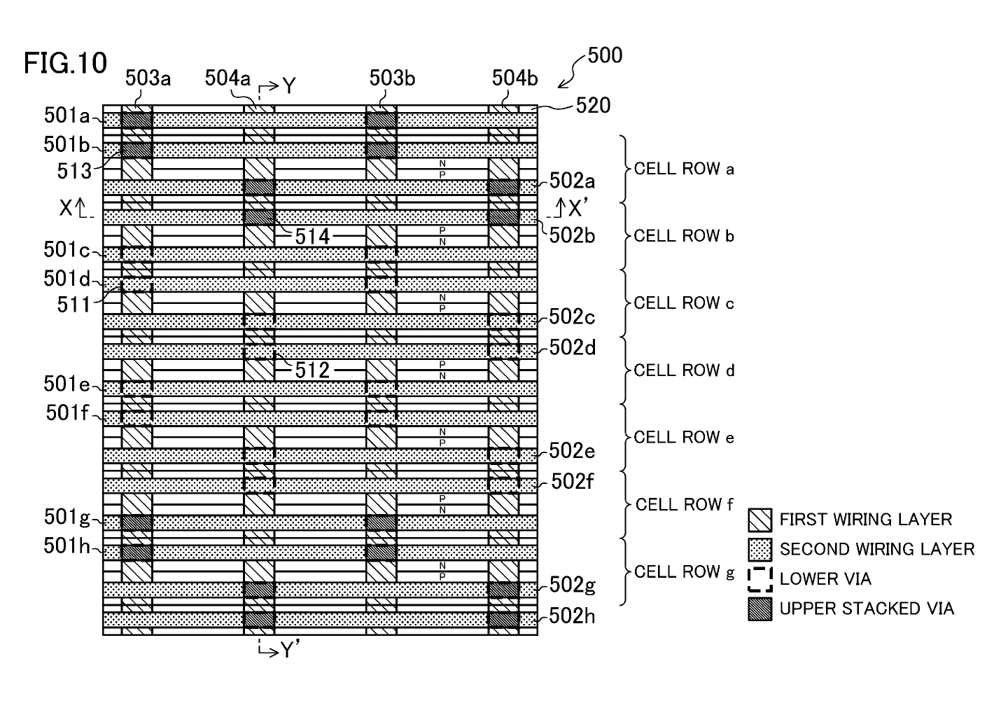

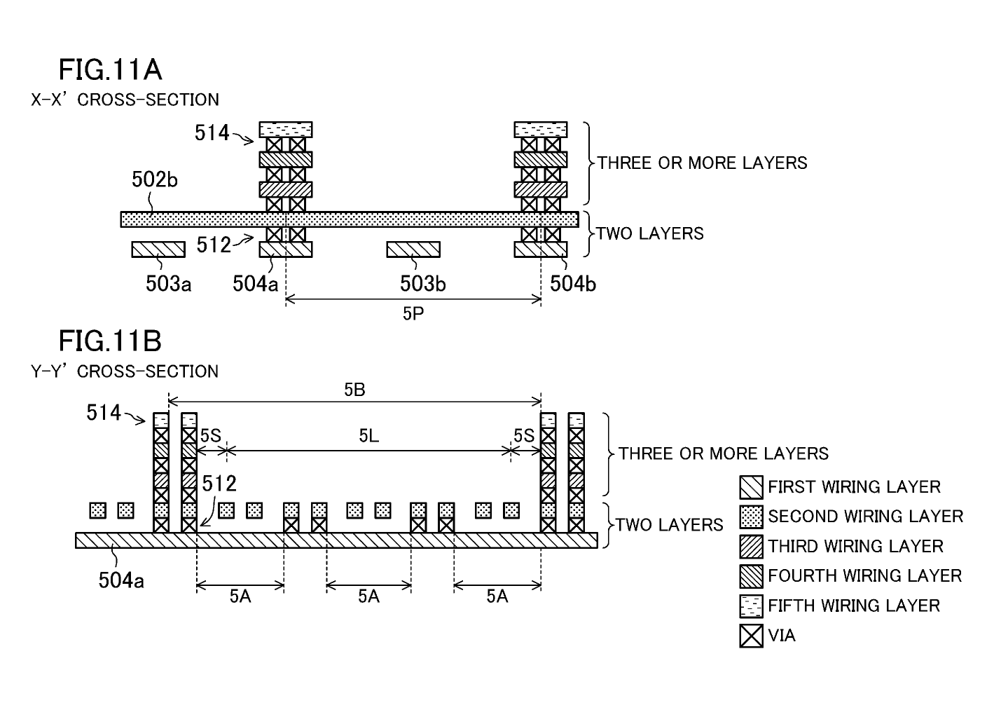

FIG. 10 is a plan view (a simplified diagram of a layout pattern) showing the configuration of a semiconductor device according to a fifth embodiment. FIG. 11A is a cross-sectional view taken along line X-X′ in FIG. 10, and FIG. 11B is a cross-sectional view taken along line Y-Y′ in FIG. 10. In a semiconductor device 500 shown in FIGS. 10 and 11A-11B, a plurality of standard cell rows (cell rows “a” to “g”) are arranged on a substrate 520 in a vertical direction (a second direction) in FIG. 10. A plurality of standard cells are arranged in a horizontal direction (a first direction) in FIG. 10 in each standard cell row.

The semiconductor device 500 has five or more wiring layers on the substrate 520. In the configuration of FIGS. 11A-11B, first to fifth wiring layers are stacked in order from the substrate 520. Signal lines in the first wiring layer are mainly used for connection between elements in the standard cell, and signal lines in the second to fifth wiring layers are mainly used for connection between the standard cells. Preferential wiring directions of the second and fourth wiring layers are the horizontal direction in FIG. 10, and preferential wiring directions of the third and fifth wiring layers are the vertical direction in FIG. 10.

Power supply potential lines 501a, 501b, 501c, 501d, 501e, 501f, 501g, 501h and substrate potential lines 502a, 502b, 502c, 502d, 502e, 502f, 502g, 502h, each placed over a corresponding one of the standard cell rows, are formed in the second wiring layer. The power supply potential lines 501a, 501b, 501c, 501d, 501e, 501f, 501g, 501h apply a power supply potential to the standard cell rows connected thereto, and the substrate potential lines 502a, 502b, 502c, 502d, 502e, 502f, 502g, 502h apply a substrate potential to the standard cell rows connected thereto.

Power supply strap lines 503a, 503b configured to supply the power supply potential and power supply strap lines 504a, 504b configured to supply the substrate potential are arranged parallel to each other in the first wiring layer so as to extend in the vertical direction in FIG. 10. The power supply strap lines 503a, 503b are connected to the power supply potential lines 501a, 501b, 501c, 501d, 501e, 501f, 501g, 501h via lower vias 511 as lower via portions. Similarly, the power supply strap lines 504a, 504b are connected to the substrate potential lines 502a, 502b, 502c, 502d, 502e, 502f, 502g, 502h via lower vias 512 as lower via portions. Each of the lower vias 511, 512 is formed by a via between the first and second wiring layers.

The power supply potential lines 501a, 501b, 501c, 501d, 501e, 501f, 501g, 501h are connected via upper stacked vias 513 as upper via portions to a potential supply portion (not shown) which is formed above the fifth wiring layer and to which the power supply potential is supplied. Similarly, the substrate potential lines 502a, 502b, 502c, 502d, 502e, 502f, 502g, 502h are connected via upper stacked vias 514 as upper via portions to a potential supply portion (not shown) which is formed above the fifth wiring layer and to which the substrate potential is supplied. Each of the upper stacked vias 513, 514 is formed by vias between the second and third wiring layers, between the third and fourth wiring layers, and between the fourth and fifth wiring layers, and short wirings in the third, fourth, and fifth wiring layers.

As shown in FIG. 11B, the lower vias 512 are substantially regularly arranged at intervals of 5A, and the upper stacked vias 514 are substantially regularly arranged at intervals of 5B. The interval 5A is substantially equal to the height A of the two standard cells shown in FIG. 3. The interval 5B is larger than the interval 5A, and in this example, is about 3 times the interval 5A. That is, the upper stacked vias 514 are arranged at a lower density than the lower vias 512 in the vertical direction (the second direction) in FIG. 10.

Similarly, the upper stacked vias 513 are arranged at a lower density than the lower vias 511 in the vertical direction (the second direction) in FIG. 10. In FIG. 11B, “5L” represents a range in the fourth wiring layer which can be used as interconnection resources for signal lines, and “5S” represents the distance from the upper stacked via 514 to the range 5L.

In the semiconductor device 500 according to the present embodiment, the power supply strap lines are formed in the first wiring layer of the five or more wiring layers, and the power supply potential lines and the substrate potential lines are formed in the second wiring layer. That is, the power line structure of the present embodiment has two wiring layers from the power supply strap lines to the standard cell rows, and three or more wiring layers above the power supply strap lines. This configuration can reduce the number of lower stacked vias from the power supply strap lines to the standard cell rows, and thus can suppress reduction in interconnection resources for signal lines.

In the power line structure of the present embodiment, the wiring direction in the wiring layers located above the second wiring layer in which the power supply potential lines and the substrate potential lines are formed is not limited by the direction in which the power lines are arranged. This allows the wiring layers located above the second wiring layer to have any preferential wiring direction as necessary.

That is, according to the present embodiment, the power supply potential lines and the substrate potential lines are formed in the second wiring layer, and the power supply strap lines are formed in the first wiring layer located below the second wiring layer. The upper via portions that connect the power supply potential lines and the substrate potential lines to the potential supply portion are arranged at a lower density in the direction in which the power supply strap lines extend than the lower via portions that connect the power supply strap lines to the power supply potential lines and the substrate potential lines. This configuration can reduce the number of via portions without increasing the value of the combined resistance in the power line structure. Thus, the power line structure can be implemented which is capable of securing large interconnection resources for signal lines while suppressing a power supply voltage drop.

In the present embodiment, the upper via portions are arranged at a density that is about ⅓ of that of the lower via portions. However, the present disclosure is not limited to this. For example, advantages of the present disclosure can be sufficiently obtained if the upper via portions are arranged at a density that is equal to or less than ½ of that of the lower via portions.

In the present embodiment, the upper via portions are positioned so as to overlap the lower via portions as viewed in the direction perpendicular to the substrate surface. However, the present disclosure is not limited to this.

In the present embodiment, each standard cell row has its own power supply potential line and its own substrate potential line. However, adjoining ones of the standard cell rows may have a common power supply potential line or a common substrate potential line. Alternatively, each of the power supply potential lines and the substrate potential lines may be arranged between corresponding adjoining ones of the standard cell rows.

In the present embodiment, another wiring layer may be provided between the substrate and the first wiring layer in which the power supply strap lines are formed. Another wiring layer may be provided above the fifth wiring layer.

In the present embodiment, the wiring width of the power supply strap line is normally equal to or less than five times the minimum wiring width of the corresponding wiring layer, namely the first wiring layer, in a region that is actually used (a region that substantially contributes to power supply).

In each of the above embodiments, two vias are provided at each layer of the via portions. However, any number of vias, which is equal to or higher than 1, can be provided at each layer of the via portions. The positions of the vias provided above and below each wiring layer need not necessarily completely match each other in the vertical direction, and these vias need only be electrically connected to the potential supply portion.

In each of the above embodiments, the upper via portions configured to supply the power supply potential and the lower via portions configured to supply the substrate potential are placed over the same standard cell row. However, the present disclosure is not limited to this.

In the semiconductor device of the present disclosure, larger interconnection resources for signal lines can be secured while suppressing a power supply voltage drop. Accordingly, the semiconductor device of the present disclosure is useful in, e.g., reducing the size of large scale integrated (LSI) circuits while maintaining their operational stability.

What is claimed is:

1. A semiconductor device, comprising:
a substrate on which a plurality of standard cell rows, each having a plurality of standard cells arranged in a first direction, are arranged in a second direction perpendicular to the first direction;
first to n^{th} wiring layers (where “n” is an integer of 5 or more) which are formed on the substrate so as to be stacked in order from the substrate, and in which signal lines can be arranged;
a power supply potential line and a substrate potential line which are formed in the first wiring layer and are placed between the standard cell rows or over the standard cell rows;
a power supply strap line formed in the m^{th} wiring layer (where 1≦m≦n/2) and extending in the second direction;
lower via portions that connect the power supply strap line to the power supply potential line and the substrate potential line; and
upper via portions that connect the power supply strap line to a potential supply portion formed above the n^{th} wiring layer, wherein
the upper via portions are arranged at a lower density in the second direction than the lower via portions.

2. The semiconductor device of claim 1, wherein
the upper via portions are arranged at the density that is equal to or less than ½ of that of the lower via portions in the second direction.

3. The semiconductor device of claim 1, wherein
the upper via portions are positioned so as to overlap the lower via portions as viewed in a direction perpendicular to a substrate surface.

4. The semiconductor device of claim 1, wherein
m=3 and n≧7.

5. The semiconductor device of claim 1, wherein
m=4 and n≧9.

6. The semiconductor device of claim 1, wherein m=2 and n≧5.

7. The semiconductor device of claim 1, wherein
multiple ones of the power supply strap line are arranged in the first direction,
the power supply strap lines are arranged at an interval of 20 μm or less.

8. A semiconductor device, comprising:
a substrate on which a plurality of standard cell rows, each having a plurality of standard cells arranged in a first direction, are arranged in a second direction perpendicular to the first direction;
first to n^{th} wiring layers (where “n” is an integer of 3 or more) which are formed on the substrate so as to be stacked in order from the substrate, and in which signal lines can be arranged;
a power supply potential line and a substrate potential line which are formed in the first wiring layer and are placed between the standard cell rows or over the standard cell rows;
a power supply strap line formed in the first wiring layer, extending in the second direction, and connected to the power supply potential line or the substrate potential line; and
upper via portions that connect the power supply strap line to a potential supply portion formed above the n^{th} wiring layer.

9. A semiconductor device, comprising:
a substrate on which a plurality of standard cell rows, each having a plurality of standard cells arranged in a first direction, are arranged in a second direction perpendicular to the first direction;
first to n^{th} wiring layers (where “n” is an integer of 5 or more) which are formed on the substrate so as to be stacked in order from the substrate, and in which signal lines can be arranged;
a power supply potential line and a substrate potential line which are formed in the second wiring layer and are placed between the standard cell rows or over the standard cell rows;
a power supply strap line formed in the first wiring layer and extending in the second direction;
lower via portions that connect the power supply strap line to the power supply potential line and the substrate potential line; and
upper via portions that connect the power supply potential line and the substrate potential line to a potential supply portion formed above the n^{th} wiring layer, wherein
the upper via portions are arranged at a lower density in the second direction than the lower via portions.

10. The semiconductor device of claim 9, wherein
the upper via portions are arranged at the density that is equal to or less than ½ of that of the lower via portions in the second direction.

11. The semiconductor device of claim 9, wherein
the upper via portions are positioned so as to overlap the lower via portions as viewed in a direction perpendicular to a substrate surface.

12. The semiconductor device of claim 1, wherein
a wiring width of the power supply strap line is equal to or less than five times a minimum wiring width in the m^{th} wiring layer in a region that is actually used.

13. The semiconductor device of claim 8, wherein
a wiring width of the power supply strap line is equal to or less than five times a minimum wiring width in the first wiring layer in a region that is actually used.

14. The semiconductor device of claim 9, wherein
a wiring width of the power supply strap line is equal to or less than five times a minimum wiring width in the first wiring layer in a region that is actually used.
